(19) United States
(12) Patent Application Publication
(10) Pub. No.: US 2026/0299518 A1
(43) Pub. Date: Oct. 1, 2026

(54) FUNCTIONAL MECHANICAL PART AND ITS SURFACE TREATMENT METHOD

(71) Applicant: The Swatch Group Research and DevelopmentL td, Marin (CH)

(72) Inventors: Christian MANASTERSKI, Rochefort (CH); Christophe VINCENT, Montperreux (FR)

(73) Assignee: The Swatch Group Research and DevelopmentL td, Marin (CH)

(21) Appl. No.: 19/489,356

(22) PCT Filed: Feb. 20, 2024
(86) PCT No.: PCT/EP2024/054286

§ 371 Date: Dec. 2, 2025

(30) Foreign Application Priority Data
Jun. 13, 2023 (EP) 23179019.7

(51) Int. Cl. G04B 15/14; G04D 3/00

(52) U.S. Cl. CPC G04B 15/14; G04D 3/0069; G04D 3/0087

(57) ABSTRACT

The present invention relates to a method for treating a mechanical part (2, 3) comprising a functional surface (8) made of NiP intended to come into frictional contact with another functional surface, said method comprising a step for oxidising and/or phosphatising said functional surface so as to artificially form a layer of oxides (9) and/or a layer of phosphates (10), respectively, on said functional surface (8), the phosphate layer (10) being a layer of Ni or Zn phosphates.

### TECHNICAL FIELD OF THE INVENTION

The present invention relates to a mechanical part comprising a functional surface intended to come into frictional contact with another functional surface when in use. It also relates to the method for treating the surface of said part.

### TECHNOLOGICAL BACKGROUND

Horology movements were designed from the outset with lubrication in order to function. This reduces friction losses and therefore the energy required to function correctly. Lubrication enables them to conserve their high chronometric performance and limits wear. However, oil or grease are elements that lead to aging due to the wear particles they contain, their oxidation, their migration and even their evaporation. The environment also plays a role, as temperature changes the viscosity properties and impedes the chronometric operation of the movement. Despite all these drawbacks, movements are still lubricated with oils and greases that are nonetheless increasingly efficient.

The crucial point in a movement's entire kinematic chain is the escapement. Although it has been dominated for centuries by the Swiss pallet design that is most widespread today, this escapement requires special attention to lubrication. From the epilame applied to the levers to force the oil to remain in contact, to the application of lubricant to the escapement wheels, every measure is taken to ensure long-term lubrication and therefore chronometric performance.

Numerous lubricant developments have been carried out with different types of oil or with a view to applying a solid plating to this Swiss pallet escapement.

For some time, the grail has been the elimination of lubrication, particularly in the escapement, which would make it possible to eradicate the problems associated with lubrication.

One method is to limit the friction phases on the escapement. The most prominent among them is the coaxial escapement, which has an architecture that minimises friction by replacing it with impacts, enabling it to function without oil. Another method is to change the escapement material. Thus, other types of escapements made with silicon or diamond have been developed to minimise friction. Pairs of materials in a functional assembly have also been developed, such as the diamond-facing ceramic pair which enables the formation of a third lubricating body.

At present, no mass-produced movement functions dry, and only movements that might be called “prototypes” have been marketed in very limited quantities.

A new solution is therefore still being sought.

### SUMMARY OF THE INVENTION

To this end, an analysis of the condition of the functional surfaces of mechanical parts that had been subjected to friction for several years was carried out. The tests were carried out on parts plated with NiP or made entirely of this material, as NiP is known to improve impact resistance. NiP or Nickel-Phosphorus is a nickel alloy containing 12% phosphorus. It is one of the high phosphorus alloys. It is non-magnetic and corrosion resistant. It is hard (350 to 450 HV at bath exit) and can also be hardened by heat treatment up to 900 HV by NisP precipitation at the grain boundaries.

Horology wheels made of electroformed NiP and steel coated with a NiP deposit were put to a “movement test” over a long period. A “movement test” is a test under real-life conditions that enables the suitability of the escapement wheel/pallet system to be assessed over a long period. Some NiP wheels tested without any lubricants performed very well over a six-year period. After stopping the test and disassembling the elements, the wheels were analysed to assess the condition of the functional surfaces. SEM (Scanning Electron Microscopy) analyses were performed on an ultra-precise microsection obtained by FIB (Focused Ion Beam) section. They revealed a “black layer” of an unknown nature, akin to a third body that seems to have formed spontaneously over the years of operation. This “black layer” was then characterised by EDX (Energy-dispersive X-ray spectroscopy) analysis to identify the elements; then by TOF SIMS (Time-of-Flight Secondary Ion Mass Spectrometry) analysis from the extreme surface down to a depth of 150 nm in an attempt to determine the chemical bonds present. The results of these analyses show that:
elements Ni, P, O, C were detected,
PO₃⁻; Ni₂PO₄; O₂⁻; PO⁻, Ni₂O₃⁻ bonds were identified.

These elements and constituent bonds of this “black layer”, show that the nickel and phosphorus that were initially present had drastically oxidised and even formed a new molecule such as Ni₂PO₄. This intense oxidation, on one hand, and the formation of a new nickel phosphate molecule, on the other, appear to be responsible for the good tribological behaviour of the escapement wheel/pallet assembly.

The inventors therefore sought to artificially reproduce, over a short space of time, what had occurred naturally over several years. The idea was to create an intense oxidation of the NiP surface using several technologies and also to reproduce as simply as possible a molecule similar to Ni₂PO₄, i.e., nickel orthophosphate of formula Ni₃(PO₄)₂. The two approaches, namely oxidation and phosphatisation, were examined separately and then together.

More specifically, the present invention relates to a method for treating a mechanical part comprising a functional surface made of NiP intended to come into frictional contact with another functional surface, said method comprising a step for oxidising and/or phosphatising said functional surface so as to artificially form a layer of oxides and/or a layer of phosphates, respectively, on said functional surface. According to the invention, the phosphate layer is a layer of Ni phosphates or, as a variant, a layer of Zn phosphates that could also improve the tribological properties.

Several options for carrying out this oxidation and/or phosphatisation treatment have been successfully evaluated using tribometers:
Dry oxidation with O₂ plasma or with a sweep of an O₂/O₃ mixture,
Germination of Ni₃(PO₄)₂ by chemical reaction (hydrolysis),
Dry Oxidation+Ni₃ (PO₄)₂ germination,
Electrolysis oxidation in an aqueous medium.

The presence of oxides and phosphates on a surface composed of NiP results in significant dry tribological gains, with stabilisation and a lower coefficient of friction relative to untreated NiP compared, for example, with ruby.

The present invention also relates to a mechanical part comprising a functional surface intended to come into frictional contact with another functional surface, said NiP functional surface having been subjected to the above treatment method and comprising a layer of Ni or of Zn oxides and/or phosphates.

Another aspect of the invention relates to a functional assembly comprising the previously-described mechanical part and another mechanical part comprising the other functional surface intended to be in frictional contact with the functional surface of said mechanical part, the functional assembly being characterised in that the frictional contact is dry.

Other purposes, advantages and characteristics of the invention will become clearer from the following detailed description, with reference to the appended drawings.

### BRIEF DESCRIPTION OF THE FIGURES

FIG. 1 is a partial view of a functional assembly comprising two parts, namely an escapement wheel and a pallet stone with contact surfaces treated according to the method in the invention.

FIG. 2 is a schematic cross-sectional view of the functional part treated with the method according to the invention.

FIG. 3 shows an electron microscope image of the distribution of Ni₃(PO₄)₂ seed crystals on the surface of a sample.

FIG. 4 shows an electron microscope image of a Ni₃(PO₄)₂ seed crystal.

FIG. 5 shows the dynamic coefficient of friction curves according to the distance travelled for the NiP/ruby pair with NiP treated by dry oxidation according to the invention for two samples and the NiP/ruby pair without NiP treatment as a comparison.

FIG. 6 shows the dynamic coefficient of friction curves according to the distance travelled for the NiP/ruby pair with NiP treated by Ni₃ (PO₄)₂ germination according to the invention for two samples and the NiP/ruby pair without NiP treatment as a comparison.

FIG. 7 shows the dynamic coefficient of friction curves according to the distance travelled for the NiP/ruby pair with NiP treated by dry oxidation and Ni₃(PO₄)₂ germination according to the invention for two samples and the NiP/ruby pair without NiP treatment as a comparison.

FIG. 8 shows the dynamic coefficient of friction curves according to the distance travelled for the NiP/ruby pair with NiP treated by oxidation in an aqueous medium according to the invention for one sample and the NiP/ruby pair without NiP treatment as a comparison.

### DETAILED DESCRIPTION OF THE INVENTION

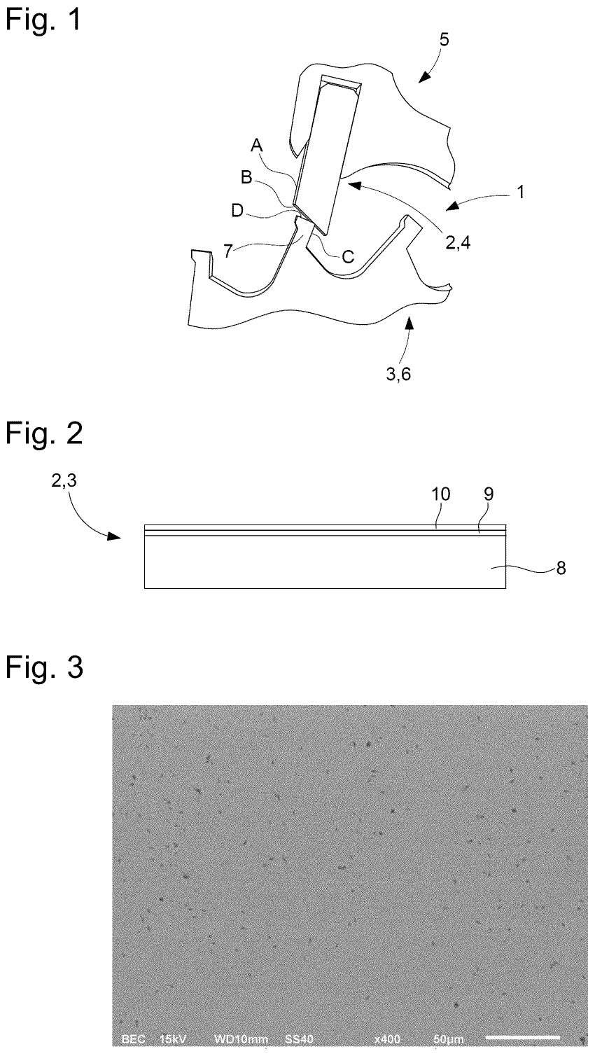

The present invention relates to a mechanical part subjected on one or more of its so-called functional or contact surfaces to friction with one or more functional surfaces of another part or of the same part. The mechanical part can be used in any system where friction is a concern. These can be applications for automotive parts, electronics, etc. More specifically, this can be a part used in the field of horology and in particular a part in the movement. Examples of such parts include pallet stones, escapement wheels, mobile axes, bearings, barrel springs and gear wheels. Said part can be in contact with another part. By way of example, in the field of horology, the functional assembly 1 shown in FIG. 1 can comprise a first part 2 which is a pallet stone 4 of a pallet 5 and a second part 3 which is an escapement wheel 6. More specifically, the pallet stone 4 has a rest plane A and an impulse plane B which engage with rest planes C and impulse planes D of tooth 7 of the escapement wheel 6. These planes A, B, C, D are functional surfaces that see heavy use and are subjected to high levels of friction and/or contact, requiring the use of special materials to reduce friction. Alternatively, one functional surface of a part can be in contact with another functional surface of the same part. For example, this can be a barrel spring formed from a blade with one face of the spring intended to be in contact with another face of the spring.

The mechanical part is at least partially made of NiP. This means that at least the functional surface or surfaces are made of NiP. The part can be made entirely of NiP or comprise a NiP plating at least on the functional surfaces. The other mechanical part comprising the other functional surface intended to be in frictional contact with the functional surface of said mechanical part can be made of a material chosen among ruby, steel and NiP treated or not according to the method of the invention.

According to the invention, at least the functional surfaces comprise oxides and/or phosphates. FIG. 2 is a schematic view of the functional surface 8 with an oxide layer 9 and a phosphate layer 10. To this end, the functional surfaces were subjected to an oxidation and/or phosphatisation treatment, with an oxidation and phosphatisation treatment being shown in the example in FIG. 2.

The oxidation treatment can be performed by dry oxidation or electrolysis. Dry oxidation can be obtained by atmospheric plasma or by vacuum plasma or thermally in an oxygen-swept oven. For example, the samples can be oxidised in a vacuum reactor under oxygen plasma or under a sweep of an O₂-O₃ blend if the equipment is fitted with an ozone (O₃) generator. The oxidation artificially created by the method is in the form of a thin, highly homogeneous layer that is darker in colour than the initial substrate. It can be assumed that the conversion layer produced is isotropic, although this has yet to be proven. Advantageously, the oxide layer has a thickness comprised between 7 and 13 nm, preferably between 8 and 12 nm. The thickness can be measured by ellipsometric analysis using, for example, a SEMILAB SE 2000 Spectroscopic Ellipsometer. Advantageously, the oxide layer has, in the CIELAB colour space (in line with CIE No. 15, ISO 7724/1, DIN 5033 Teil 7, ASTM E-1164), an a* value comprised between 2.2 and 3 and a b* value comprised between 8 and 12, preferably between 9 and 11.

The phosphatisation treatment can be performed by germinating phosphate on the NiP substrate. This treatment consists of creating seed crystals that are conducive to good tribology. Preferentially, this is a nickel orthophosphate Ni₃ (PO₄)₂ that is relatively easy to germinate. A zinc phosphate (Zn₃(PO₄)₂) can also be germinated.

Germination involves hydrolysis, i.e., breaking a covalent bond in an aqueous medium. Its principle consists of combining nickel in the form of nickel chloride hexahydrate (NiCl₂,6H₂O) with phosphate in the form of potassium di-hydrogen orthophosphate (KH₂PO₄). These 2 molecules do not react with each other when combined. On the other hand, if a hydrolyser such as urea (NH₂CONH₂) is added and the mixture is heated to a certain temperature, typically between 70° C. and 100° C., the two molecules break up to form a third one, nickel orthophosphate, according to the following reaction chain:

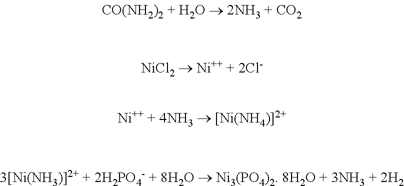

Typically, the nickel chloride hexahydrate is in an aqueous solution with a molar concentration comprised between 0.01 and 0.06 M, the potassium di-hydrogen orthophosphate is in an aqueous solution with a molar concentration comprised between 0.02 and 0.09 M and the urea in an aqueous solution with a molar concentration comprised between 0.01 and 0.15 M.

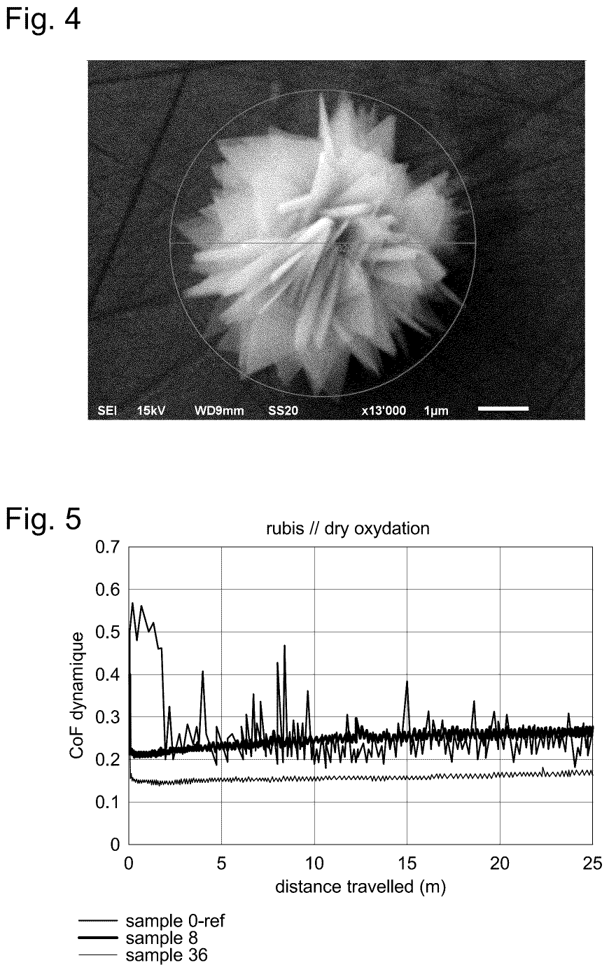

Nickel orthophosphate germinates on NiP. The germination has an average density of 35 seed crystals per 100×100-micron square. This is illustrated in FIG. 3. This means that there are 0.0035 crystals per square micron. The crystals have a leafy appearance, forming a petal-like structure. A seed crystal measures around 5 to 6 microns (see FIG. 4) and adheres strongly to the NiP surface.

There are alternative methods for generating nickel orthophosphate (Ni₃(PO₄)₂). To take place, the above hydrolysis reaction requires a source of energy. In this case, it was the heat that enabled this reaction to occur. However, this energy could conceivably be added using a cold plasma (under reduced or atmospheric pressure) or using ultrasound energy.

In addition, other reactions lead to the formation of nickel orthophosphate in aqueous or solid media. In this respect, we can cite:
Saifon Kullyakool et al in “Determination of kinetic triplet of the synthesized Ni₃(PO₄)₂_8H₂O by non-isothermal and isothermal kinetic methods” (Journal of Thermal Analysis and calorimetry, February 2014):
   NiSO₄ and Na₂HPO₄ at 90° C. for 1 to 5 days
   NiSO₄ (0.5 M) and Na₃PO₄ (0.5 M) at 70° C. for 1 day.

In these last two cases, a nickel orthophosphate precipitate is obtained.

Two other methods are described in:
Ismaël Saaddoune et al in “Synthesis characterisation, Electrochemistry and in situ XRD investigation of Ni₃ (PO₄)₂ as negative electrode material for lithium-ion batteries” (Chem ElectroChem 10.1002/celc.202001065):
   Solid-state synthesis of Ni₃ (PO₄)₂ using NiO and ammonium phosphate (NH4)2HPO4. These ingredients are mixed (powders) then calcined in stages of from 200 to 900° C. in an oven with no gas protection.
Lowie Henderick et al in “Plasma enhanced atomic layer deposition of nickel and cobalt phosphate for lithium-ion batteries” (2022,51,2059 Dalton Transactions) suggest Nicp₂ (cyclopentadienyl nickel) and TMP (trimethyl phosphate) precursors in O₂ plasma at 300° C.

A nickel orthophosphate film can also be deposited using ALD (Atomic Layer Deposition) technology. This case involves a film rather than seed crystals.

Samples were prepared with oxidation and/or phosphatisation treatment according to the invention and tribological tests were performed on these samples.

Oxidation treatments were performed using vacuum dry oxidation. The latter was obtained using a plasma vacuum treatment. The equipment used is the “Denton Discovery PVD/PECVD” apparatus. The samples are placed in a vacuum chamber. They are first heated to between 10° and 200° C. The Ar gas, which is highly plasmagenic, is introduced into the chamber, where the substrate carrier is subjected to a negative potential that can vary between 500 and 1000 V. This generates power varying between 90 W and 380 W in the Denton apparatus used. The pressure is set to 15μ bar. Typically, it can be between 10 and 30 μbar. An Ar plasma lights up. The first step is to clean the surface by bombarding it with relatively heavy Ar ions for a few minutes. Once the surface has been decontaminated, the Ar is gradually replaced by O₂ until a plasma of pure oxygen is obtained, which then takes on a yellow hue. This oxygen plasma will generate the expected oxide layer. This highly energetic plasma has an electron temperature of around 100,000° K (one hundred thousand degrees Kelvin). This temperature, which is not physical, merely reflects the agitation and intense reactivity of the atoms confined in this plasma.

Around ten tests were carried out under different conditions in which a number of parameters are set: the pressure in the vacuum chamber as well as the flow of Ar and O₂ while other parameters are variable: the applied voltage, the temperature of the chamber and the dwell time of the sample in the chamber.

In addition, two additional tests were carried out on ALD Encapsulix equipment, which features an ozone generator. This O₃ gas is particularly reactive but also very unstable and ephemeral. This generator supplies an O₂/O₃ gas blend that can be used with or without plasma and which sweeps the samples in a chamber in which a vacuum has been created beforehand as with the previous equipment. One test is carried out with a plasma at the risk of destroying the O₃ molecule; whereas the other is carried out in the form of a simple chemical sweep with no plasma.

10 tests were run on the two apparatuses described above. The tribological results given below are presented for one sample of each. One of them, number 36, was carried out in the ALD apparatus with a chemical sweep (with no plasma) of an O₂/O₃ blend for four hours. Another, number 8, was produced in the PVD apparatus, with 700 V (172 W) for 15 minutes at 150° C. (FIG. 5).

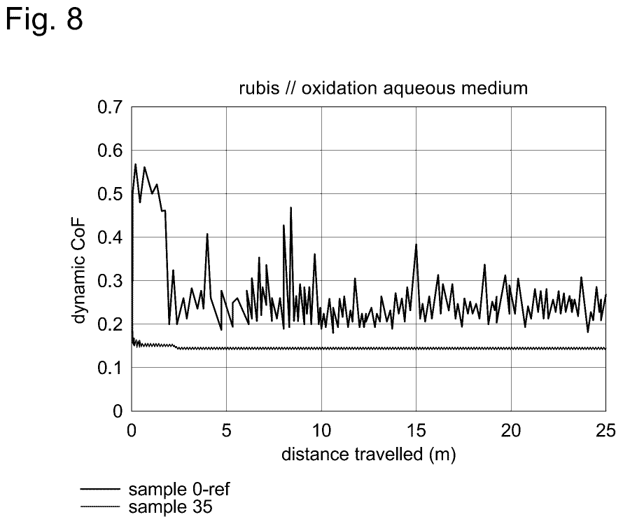

Oxidation treatments were also carried out in an aqueous medium. Oxidation is performed by simple electrolysis of water, by connecting to the positive (+) pole of the electrodes. O₂ is then released, as is well known to the person skilled in the art. The variable parameters are:
Type of solution
   Electrolytic degreasing bath (alkaline),
   KOH solution at 1M (alkaline).
Anodic oxidation in H₃PO₄ medium at 0.1 M (acid),
Dipping (i.e., chemical dipping) in alkaline, neutral and acidic media.
   The result for the tribology test is presented below for sample number 35 (FIG. 8).

For the phosphatisation treatment, Ni₃(PO₄)₂ was germinated according to the following protocol:
Nickel source: nickel chloride hexahydrate (NiCl₂, 6H₂O) dissolved at a rate of 1,570 mg for 200 cc of water, i.e., a 0.033 M solution,
Phosphate source: potassium dihydrogen orthophosphate (KH₂PO₄) dissolved at a rate of 1,794 mg for 200 cc of water, i.e., a 0.066 M solution,
Source of hydrolyser: urea (NH₂CONH₂) dissolved in different proportions:
   300 mg per 200 cc of water (0.025 M solution),
   600 mg per 200 cc of water (0.05 M solution),
   900 mg per 200 cc of water (0.075 M solution),
   1,200 mg per 200 cc of water (0.1 M solution).

These four concentrations have an influence on the dimensions of the sheets (length, width and thickness) during seed crystallisation. Then, 1 cc of surfactant (Sodium Lauryl Sulfonate) is added. The samples are cleaned beforehand and activated by cathodic electrolytic degreasing at 5 A/dm². They are then vertically immersed in the hydrolysis solution. The samples are heated to 90° C. and kept there for 45 minutes once the solution has reached the correct temperature. After this time, the samples are taken out, rinsed and dried.

The fixed parameters are as follows:
Concentrations of reagents (NiCl₂ 0.033 M & KH₂PO₄ 0.066 M),
Hydrolysis temperature (90° C.).
   The variable parameters are as follows:
Hydrolyser concentration,
How long the plates are kept in the beaker,
pH of the solution.
   In addition, a few samples are abraded with an abrasive disc (P4000 or 5 μm) in the hope of creating more germination sites.

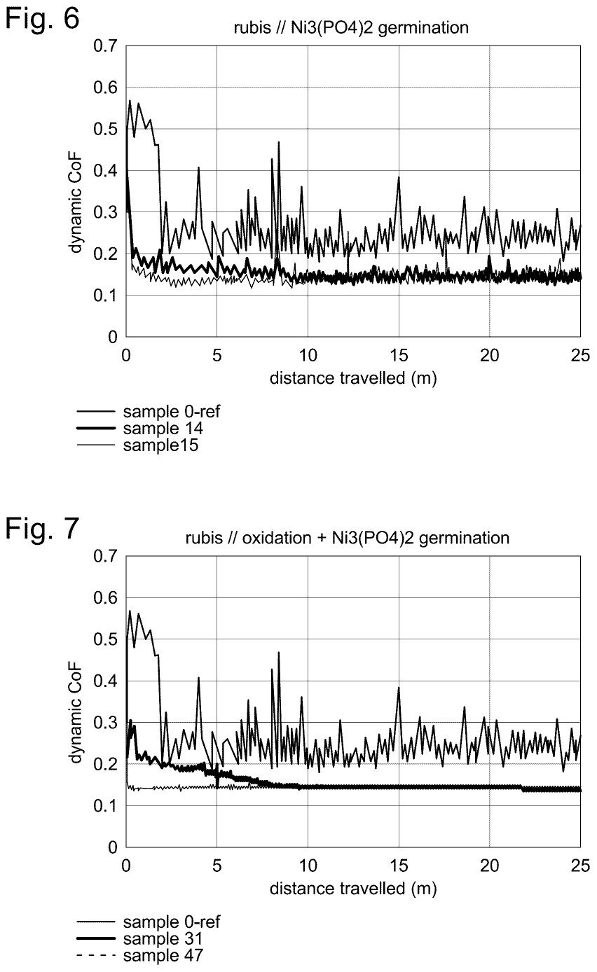

24 samples were treated. The tribological results are presented below for one sample, number 15, treated with the maximum urea concentration of 0.1M for 45 minutes at a pH of 4.08 and for sample number 14, treated under the same conditions but for 30 minutes (FIG. 6).

Samples were also prepared by combining the two treatments with preferentially first the oxidation treatment, followed by the phosphatisation treatment. Some samples were subjected to the dry oxidation treatment described in sample 8 above, followed by germination with 750 mg of hydrolyser (urea). It should be noted that in order to preserve the previously plasma-oxidised surface, electrolytic degreasing prior to germination is carried out using anodic degreasing rather than cathodic degreasing.

Tribological tests were conducted in alternating linear mode against a Ø2 mm ruby ball. The test conditions are as follows:
Normal effort: 1 mN,
Maximum sinusoidal speed: 10 mm/s,
Amplitude: 4 mm,
Distance covered: 25 m,
Condition: dry.

The benchmark, consisting of a rough NiP disc from the LIGA (Lithographie Galvanoformung Abformung [lithography, electroforming, moulding]) manufacturing method, was tested with tribological results showing a significant change in the coefficient of friction:
Start-up above 0.5,
Lapping phase at 0.5,
Drop to 0.25,
Stabilisation at 0.25 with numerous peaks.

All tests were performed in the same configuration and compared to this benchmark.

In FIG. 5, it can be seen that dry oxidation makes it possible to stabilise the CoF but also to limit the lapping phase of the NiP. One significant advantage in terms of CoF gain is visible in the oxidation using an O₂/O₃ sweep (sample 36).

FIG. 6 shows that germinating Ni₃(PO₄)₂ limits the CoF peaks and lowers the CoF to 0.15 when dry. The CoF drop is very rapid at start-up, thereby limiting the lapping phase.

With oxidation in an aqueous medium, FIG. 8 shows a drop in and stabilisation of CoF at 0.15 dry with an extremely short lapping phase.

Samples combining the two treatments (FIG. 7) show a drop and stabilisation of the CoF at 0.15 dry. Depending on the degree of germination, the most noticeable impact concerns the lapping phase, which is more or less long, but the CoF at start-up is significantly lower than for the benchmark.

Colorimetry measurements were also carried out on samples oxidised by ALD and on comparative samples that had not been subjected to accelerated oxidation treatment but to natural oxidation, which can take several years. Colorimetric values L*a*b* were measured on the polished samples with a KONICA MINOLTA CM-3610A spectrophotometer under the following conditions: SCI (including specular reflection) and SCE (excluding specular reflection), 8° inclination, 4 mm diameter SAV measurement zone. The results are given in the table below.

| | L* | a* | b* |
|---|---|---|---|
| Benchmark chip | 73.36 | 1.97 | 6.07 |
| ALD oxidised chip | 69.32 | 2.56 | 9.60 |

The colour difference between the two chips is determined on the basis of the delta E, which is calculated on the basis of the L*a*b* values as follows with L₁^{*}, a₁^{*} and b₁^{*} referring to the values of the benchmark chip and L₂^{*}, a₂^{*} and b₂^{*} to the values of the chip oxidised with the treatment according to the invention.

$$Δ {E}^{*} = {[ {( {L}_{2}^{*} - {L}_{1}^{*} )}^{2} + {( {a}_{2}^{*} - {a}_{1}^{*} )}^{2} + {( {b}_{2}^{*} - {b}_{1}^{*} )}^{2} ]}^{1 / 2}$$

This results in a delta E of 5.4. It can be concluded that the treated sample has darkened relative to the benchmark sample. An oxidation layer therefore developed on the surface of the sample. This oxidation layer was characterised more precisely by ellipsometric analysis. It appears that the thickness of the layer is between 9 and 10 nm. On the other hand, its index of between 1.8 and 2 shows that the composition of this layer is not preferentially composed of NiO, to which the index of 2.1818 does not correspond, but rather of phosphorus oxides, which does not preclude the presence of a minor amount of NiO. Phosphorus trioxides (P₂O₃), phosphorus tetraoxides (P₂O₄) and phosphorus pentoxides (P₂O₅) have an index of around 1.82, which is within the identified range. This is a logical result, as NiO reaction kinetics are lower than those of phosphates, which predominate and form more easily and more quickly than NiO.

In conclusion, the presence of oxides and phosphates on a surface composed of NiP results in significant dry tribological gains.

1-17. (canceled)

18. A functional assembly comprising a first mechanical part comprising a first functional surface made of NiP and a second mechanical part comprising a second functional surface intended to be in frictional contact with the first functional NiP surface of said first mechanical part (2, 3), in which the first functional NiP surface comprises a layer of oxides and/or a layer of phosphates, respectively, the phosphate layer being a layer of Ni or of Zn phosphates, the frictional contact between the first and second mechanical parts being dry.

19. The functional assembly according to claim 18, wherein at least the second functional surface of the second mechanical part is made of a material chosen among ruby, steel and NiP.

20. The functional assembly according to claim 18, wherein the second functional NiP surface comprises a layer of oxides and/or a layer of phosphates, respectively, the phosphate layer being a layer of Ni or of Zn phosphates.

21. The functional assembly according to claim 18, wherein the layer of Ni or of Zn phosphates comprises seed crystals.

22. The functional assembly according to claim 18, wherein these seed crystals are Ni₃(PO₄)₂ seed crystals.

23. The functional assembly according to claim 18, wherein the oxide layer has a thickness comprised between 7 and 13 nm.

24. The functional assembly according to claim 18, wherein the oxide layer comprises predominantly phosphorus oxides.

25. The functional assembly according to claim 18, wherein the oxide layer has, in the L*,a*,b* colour space, an a* value comprised between 2.2 and 3 and a b* value comprised between 8 and 12.

26. The functional assembly according to claim 18, wherein the functional assembly is a part in a horology movement.

27. The functional assembly according to claim 18, wherein the functional assembly is a mechanical part chosen among a pallet stone, an escapement wheel, a mobile axis, a bearing, a barrel spring and gear wheels.

28. A method for treating a mechanical part of a functional assembly according to claim 18, said method comprising a step in which said functional surface is oxidised or phosphatised so as to artificially form a layer of oxides and/or a layer of phosphates, respectively on said functional surface, the phosphate layer being a layer of Ni or of Zn phosphates.

29. The treatment method according to claim 28, wherein the oxidation step is carried out by dry oxidation, by atmospheric plasma, by vacuum plasma, by sweeping with an O₂-O₃ blend with or without plasma, or thermally in an oven swept by oxygen or by oxidation by electrolysis in an aqueous medium.

30. The treatment method according to claim 28, wherein the phosphatisation step is carried out by ALD deposition to form a phosphate film or by chemical reaction to form phosphate seed crystals.

31. The treatment method according to claim 28, wherein further comprising an oxidation step followed by a phosphatisation step.

32. The treatment method according to claim 28, wherein the oxidation step is dry oxidation with the following sub-steps:
heating the mechanical part to between 10° and 200° C. and placing said mechanical part on a substrate carrier in a vacuum chamber,
introducing Ar into the vacuum chamber with the substrate carrier subjected to a negative potential comprised between 500 and 1,000 V.

33. The treatment method according to claim 28, wherein the phosphatisation step is carried out by chemical reaction between nickel chloride hexahydrate (NiCl₂,6H₂O), potassium di-hydrogen orthophosphate (KH₂PO₄) and urea (NH₂CONH₂).

34. The treatment method according to claim 33, wherein the nickel chloride hexahydrate is in an aqueous solution with a molar concentration comprised between 0.01 and 0.06 M, the potassium di-hydrogen orthophosphate is in an aqueous solution with a molar concentration comprised between 0.02 and 0.09 M and the urea is in an aqueous solution with a molar concentration comprised between 0.01 and 0.15 M.
